(19) United States
(12) Patent Application Publication
(10) Pub. No.: US 2010/0194497 A1
(43) Pub. Date: Aug. 5, 2010

(54) MANAGEMENT OF ACTIVE ELECTRONS

(76) Inventors: Claude Annie Perrichon, L'Isle d'Abeau (FR); Francois Giry, Challes les Eaux (FR); Pierre Piccaluga, Prangin (CH); Laurent Couderc, Villeneuve Les Avignon (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(21) Appl. No.: 12/303,012

(22) PCT Filed: Jun. 2, 2006
(86) PCT No.: PCT/FR2006/001253

§ 371 Date: Apr. 19, 2010

(51) Int. Cl. H03H 7/00

(52) U.S. Cl. 333/167

(57) ABSTRACT

The present patent application is the product of a thorough study of the management of electrons, which, by nature, have a double personality: the corpuscular aspect, and the undulatory aspect, and which are known as radiant electrons because they escape from electric wires and cause operational disruptions. These radiant and inoperative electrons disrupt the active electron activity that manages the original signal. The optimal measurement is the sound revealing the intermodulational distortions in real time, whereby the temporal distortions of the electric activities can be calibrated. This diagnostic enables definition and calibration of the time and amplitudinal values of these electrical forces, which have electron voids. This alternation of electron voids disrupts the linearity of movement and creates vibration. In electroacoustics, it adds sound pulses, thereby adversely affecting proper sound reproduction. The devices eliminate electron pollution, thereby enabling the electrical charges of the batteries to be doubled while reducing computer overheating. The devices are suitable for use in the world of electricity in general, lighting and all electrical machines, as well as computers and control computers for on-board management processes. The method and devices generate a new active electric current in real time (RTE) which is dependent not on the rectification modulation but on the actual position of the non-agitated electrons.

For years, despite progress, electrical apparatus has produced noise through the cyclic vibrations emitted. More unpleasant, shocks are occasionally received from electric discharges. Televisions radiate when switched on, computers combine all the drawbacks, noise, magnetic radiations, and fingers on keyboards feel an unpleasant sensation of weak current. In airports, it may be appreciated that no filling with kerosene can take place without perfect earthing, in short we are immersed in electricity in the air, in objects, on us, everywhere, there is something happening with uncontrolled currents which build up and wander around. In high fidelity, whatever the quality and price, the sound seems to escape us, perturbed by over-oscillations which mask the real sound. The latest documentation regarding the electron of February 2006 indicates that the electron exists either in particle form, or in wave form. The electron is known only through its effects, electrical energy or magnetic field radiation or in the transient phase in the form of luminous radiation. In electrical applications, we can accept that it is fast and very reactive, giving rise to back electromotive forces. However, it may also be said that it has three notable aspects, one is energy, the other is information through the wave, the third is the radiation by the induced magnetic field or static electromagnetic charge. There are some electrons which are more propitious for serving the electric force and others the self-induced radiations. It may be said that the electrons are distracted and that some of them, the active radiation, wish to leave the channeling of the copper wires. There is another radiation set up like a sheath around the conducting wires which generates a skin effect around the surface of electric cables, a magnetic fog. It is thus possible to picture two kinds of electrons that are always naturally available in electrical wires, between the electrons available for the work of transferring electrical energy and others for electrical radiation, thus accounting for the two existential aspects of electrons, the particle aspect for electrical energy and the wave aspect for magnetic radiations.

The present patent application is aimed at sorting the active electrons with electrical energy and at helping to extract from the circuit the irradiant electrons that are more propitious to the magnetic fields which generate currents or electrostatic and electromagnetic fields. These magnetic charges build up on the structures or are irradiated directly into the ambient air. The management of the back electromotive forces disturbs the system a little more by being added on top of the original signal. These effects of the current from back electromotive forces and the inherent energies of the radiant electrons tending to leave the electrical wires will disturb the transmission of electrical energy originally desired. There is a real confusion of the use of electrons. The electronic nature of the dual activity of electrons is not so simple, and their behaviors must not be ignored. Sorting is necessary in order to organize the electrons within the best ground conditions before they are activated in any form, thereby losing the available established order of electrons before any structural modification. It is expedient to put in order the electrons in a well-oriented stable quiescent phase, and the others, which have a tendency to escape and brake the fluid flow, must be removed.

The effects of the dual personality of the electrons present in electrical circuits induce sound disturbances, the creation of vibrations in machines, or bugs in computers which overheat, through excess buildup of undesirable electromagnetic charges, which have to be corrected. A surplus of the electrons close to the electrical actions will have consequences for the velocity and nature of the information. The electromagnetic tendency will disturb the dynamic motion through excess electromagnetic charges which disturb the course of the active electrons through the conductors or around them.

The best measure, for revealing the phenomenon, is sound which shows real-time intermodulation distortions, thereby making it possible to calibrate the temporal distortions of the electron activities. This diagnostic makes it possible to define and grade the times and the values of amplitudes of these electric forces contained in the electric wires and disrupting the positions of the active electrons. Sound marries together perfectly the forces of the useful power with the information waves which requires little power but is carried by it. Disorder between power and information is a real acoustic distortion, to this is added the true temporal activity which is in part the disturbances of the position of the electrons becomes random. In the law for the electric current, field path current, the field necessarily intervenes in the middle of the active electrons, this forming part of the electronic nature of the charge of the electrons. This is the case in all motors which, activated by coils, react on magnets or a secondary, so as to attract or repel a mechanical part. The back electromotive force is set up briefly, flows along the wires and generates small mechanical pulsations. This alternation disturbs the linearity of the motion and creates vibrations. In electroacoustics, it adds sound pulses, or creates electron voids, electron vacancies at the very moment at which a note ought to exist, thus hindering proper sound restitution. In hearing aids, there is a hindrance in the form of imposed resonance, this being an electrical over-excitation of the back electromotive forces which adds background sound, an echo, an electrical Larsen preventing the sound activities from being intelligible. In order to get out of this zone of interference, the patient turns up the volume but this hindrance remains present, and no servocontrol mechanism has been able to settle this problem which is of another order, that we are unveiling and putting forward here.

The A.C. earth current delivered by power stations agitate electrons, which lose their fundamental quiescent conditions, this is the condition of perfect use before any activation. The condition of the agitated electrons always remains present despite a single or double or sophisticated rectification of the current. Because it is the stable position of the electrons before any agitation which is useful, the present invention intervenes on the nature not of the form of the modulated current, its modulation but on the stable quiescent position of the electron which is the primordial condition of every electrical activity, of information or power, failing which there is fragmentation of the information or of the signal or of the energy, the current of electrons being itself fragmented. A picture for comparison is a velvet fabric which assumes undulating reliefs, not inasmuch as the hairs of the velvet go in all directions, they must remain brushed in the right direction, or else the appearance is ugly. The same holds for electrons, where a rectification of the modulation of the voltage of the current is not concerned, rather the position of the electrons is concerned, the latter having to all be in the quiescent condition, which is a structural condition of the very nature of electrons. The voltage modulation which generalizes the whole of the flux of the electrons is not associated or concerned, rather their individual position one by one, as carried out by the present method. The condition of diodes should not be seen in this, but rather a novel, continuous, type of current that may or may not be of a wave nature, but none of whose electrons is now agitated. This is a novel real time execution (RTE) current current which no longer generates malfunctions on machines and gives genuine gentle and regular pleasure to users. This novel real time execution current is not fragmented by the absence of agitated electrons from among the other active ones. The method is to drain off, to divert this self-induced current from the back electromotive force, which flows counter to the original information and the radiant electrons which disturb the fluid flow desired for electrical control. These electrical disturbances are extracted from the electrical circuit so as not to constantly disturb the initial original information as to what follows, it must be a current (RTE) which is always free of all earlier memories of actions, a new current from which the information regarding previous actions has been removed.

The method seeks to divert, release this energy of agitation from past experience, which is a surplus of energy that is unsuited to the useful function to be carried out at the moment. The old residual formations remain as electromagnetic and electrostatic pollution which encumber the electrical circuit, or act in proximity. Let us not forget that the electron allows memory storage; it is therefore proper to think about and act so as to erase the previous modalities of electrons.

The conversion of this energy by the piezoelectric trap makes it possible to remove the radiant self-induced energy of the electrons that have acquired this radiant nature. The latter are expelled from the electrical supply circuit by passing this information over at least one choke, which through its design eradicates the electrons which have a tendency to leave from the sides of electrical wires, and cleans the electrical circuits of the inoperative electrons, freeing the path of the active electrons. The energy of the polluting radiant electrons is removed in the form of mechanical vibrations. The trap is constituted by the apparatus consisting of the choke or chokes which remove the radiant electrons which are thus ejected from the electric wires. An electromagnetic potential difference generated by the choke and the formula of piezoelectricity where they are immersed causes the radiant inoperative electrons, which excite the piezoelectricity, to jump. The self-induced electromagnetic current is thus eradicated and definitively extracted from the electrical circuit, which becomes clean. Indeed, the removal of electromagnetic energy through the use of the piezoelectricity of this method cleans the main electrical circuit of this pollution continuously and not through a voltage threshold like a diode, which is very different.

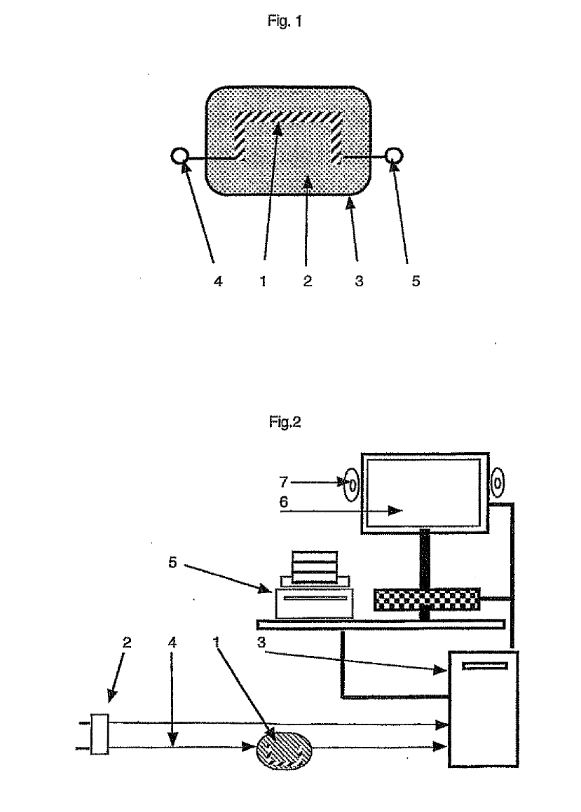

Of the dual nature of the naturally present electrons, just one part is efficacious and propitious for the proper operation of electrical apparatus. This method is like an electric current cleaning filter which has kept the old excitations. What surprises us is the improvement in the charge of cells, which is either 50% or even doubled through this principle which arranges and organizes the active electrons very efficiently. This means that there were electron voids or vacant electron spaces, or ones that were occupied but inactive or unsuitable. The results for sound reproduction equipment are astounding for musical fidelity, with this novel current reworked in its fundamental structure of the electrons themselves and not the modulation curve. This is a break in the surface vision with the fundamental conditions of matter itself within its very existence. The absence of electron holes makes it possible to provide all the information in real time as against vacant holes which give rise to untimely, irregular discharges of the electrons. In photo equipment we observe an increase in the graphical sensitivity. A very sharp improvement in the use of various files and the absence of blocking of functions are observed in computers. Lower temperature operation is observed. Printers operate better with less noise and higher graphical definition. The production equipment FIG. 1 for managing the sorting of the current of active electrons and of those which are self-induced for the magnetic radiation is a piezoelectric activated by the voltage across the terminals and in the choke by the passage of the supply currents. At least one choke (1) is made of copper wire or some other conductor or super conductor, for example. In this case, copper or aluminum of 1.5 square millimeters is wound over about 10 turns over a diameter of 10 millimeters. The choke is immersed, embedded in a paste (2) for piezoelectricity which converts the voltage of the radiant electrons which swerve off and come out of the wires while exciting the piezoelectricity, in the form of vibratory excitation through mechanical motions, the purpose of this being to absorb the surplus of inoperative, spurious, radiant electrons. This induced current is consumed in the form of mechanical motion by the piezoelectricity. The magnitude of the coil or coils depends on the modulated current. The apparatus is a passive component which is covered with a material (3) to avoid the spurious sounds generated. We have carried out trials in acoustics, with the rubber or plastic mechanical protection (3) of the soundproof cladding, so as to avoid the known acoustic disturbances. This apparatus gives a novel, continuously regulated RTE current of electrons and does not depend on the form of the modulation. It shows the removal of the electromagnetic disturbance of the self-induced negative feedback course as a continuous action. This part is mounted on an electrical supply circuit via the two lugs, one at the input (4), the other at the output (5) of the item or items of apparatus placed on the supply circuit of one or more wires of a motor for example. The apparatus makes it possible to optimize the electrical operation of machines and to continuously remove the surplus of nonactive spurious electrons that are naturally present and which are trapped and evacuated from the main electrical circuit. The manufacture of the choke or chokes may be a one-way or reversed winding or else the winding is turned over on itself like a horseshoe FIG. 1. The item or items of apparatus (1) FIG. 2 may be mounted on one or more electrical sockets (2), on the mains of a house, or incorporated into the machines on one (4) or more phases. The latter solution makes it possible to grade the apparatus according to the exact power of the radiant electrons to be channeled out of the electrical circuit. In the field of high fidelity, the apparatus may be mounted at the input of any loudspeaker or amplifier on one phase or on both. The apparatus relates to the optimization of any electric machines (3, 5, 6, 7) which rotate in perfect linearity, or for lighting. The piezoelectricity apparatus affords incredible performance as regards acoustic clarity without over-oscillation in the field of audiovisual. The same holds in the field of image reproduction, such as televisions or cinema, for example, for better definition of reliefs, fine and vivid colors with good contrast for the direct viewing of objects or in reprography, owing to a current which is not fragmented by the continuous presence of quiescent active electrons available to the action without being polluted by agitations.

None of the examples cited limits the realization of the method, which determines a novel RTE current. Applications extend to the field of automobiles, aviation, boats. Indeed, despite the DC current in the automobile sector, a keen improvement is observed in the onboard sound audio together with a modification of the engine torque which is larger at lower revs. On boats the propellers no longer cavitate. Tire grip in the automobile sector is better on account of regularization of the controls of engines that are more agitated by fragmentations of current due to the electrons agitated by the alternator.

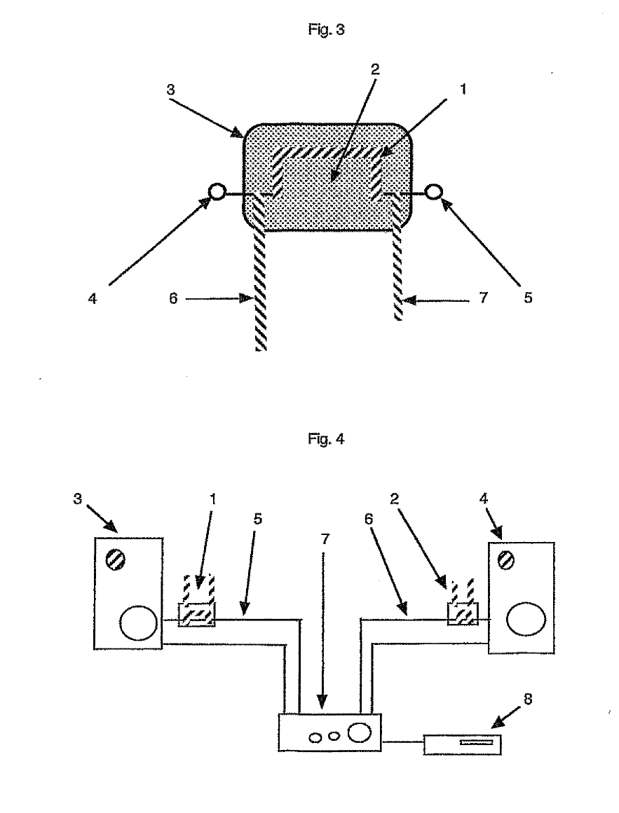

On the basis of this apparatus, we are prosecuting an extension of application which is a specific variant of the method for high fidelity for magnetic fields which radiate into ambient space out of electric wires from where they escape naturally. According to FIG. 3, the apparatus receives across the terminals of the immersed choke at least one choke, in the case of this embodiment two chokes (6-7) which are installed across the terminals of the immersed choke (1) and mounted freely in the open air, in the listening space. Indeed, when sounds are involved, there are multiple simultaneous electrical modulations of high frequencies which cause strong interaction between the magnetic inductions in the wires and in the air. The immersed choke (1) is excited by the electrical inductions of the back electromotive force of the coil or coils of the loudspeakers. These back electromotive forces are produced, among other things, by the direct audio electrical modulations which stem from the return of the current caused by the inertia of the masses which cannot transform the information of electric pulses into mechanical motion. The information is in electrical format with different and transitory velocities which will get trapped by the chokes of our apparatus of FIG. 3. Since we are dealing with lost audio electrical information, we transform it into mechanical vibrations through the piezoelectricity in mechanical form on the one hand, but also under these propitious conditions into an electromagnetic form for the remaining micropulses of an ultra fast nature which interact in the electron structures of the air. The reactive formula is prepared for all the audio frequencies of the piezoelectricity according to the ultra-sensitive piezoelectricity matter (2) in the immersed choke (1).

The preparation is an optimization of energy transformation, so that part of the trapped electrical energy is emitted mechanically by the immersed choke as far as possible, and that the remaining electrical energy is emitted electromagnetically in relation to the electromagnetic emissions emitted by the hifi system. For the first phase of mechanical transformation, it is the principle of this method which is applied. For the second phase of the electromagnetic emission, this application is specific to the electromagnetic charge dissipated naturally into the air by the electrical apparatus. At least one open air choke is activated by the impedances of magnetic resonances in the air and in tune with those radiated in the piezoelectricity, by oscillatory beating of magnetic coupling with the immersed choke. The choke in the air is soldered to the terminal of the immersed choke. The setup complies with the acoustic phases through the length of the unfurling of the external winding or windings in the ambient air. The question is to know whether this electromagnetic function exists on the retained transitory pulses, and if it does, how do we perceive it? The open air choke consists for example of 11 non-adjoining turns of an electrical wire of 9/10 diameter, wound over a diameter of 10 millimeters. The wire is made of conventional electrical coil copper, but the material could be gold, titanium or stainless steel for example. This choke is stretched to a length of 8 centimeters for listening, constituting a first trial, and then it is shrunk back to 2 centimeters for a subsequent listening constituting a second trial. The first trial gives remarkable spatiality, exceptional superiority of audio listening with a great deal of space, this being the presence of the audible harmonics. The second trial in the shrunken mode of the choke, shows that the sound is of an aggressive tonality, with no space, hollow, tense, metallic, this being an excess of magnetic resonance in the high middle register where the harmonics disappear. The harmonic comb extends and shifts, allowing or disallowing the overlapping of the sound components which disappear or appear in synchronous or asynchronous phases with the beats of the oscillatory motions managed by the feedback of the chokes which also match to a small extent with the impedance of the air which is more or less permeable to the course of the sounds. Demonstration of the apparatus produced leaves no doubt with regard to the possible adjustable electromagnetic matching of the external choke or chokes with the associated sound effects. The external chokes are coupled with the immersed choke which is of like nature and may comprise from 5 to 22 turns, the whole being curved into a horseshoe, maximum efficiency is not achieved beyond 40 turns. Through these tests the science of sound opens up a dimension in the novel sound management of acoustic reproduction, through electromagnetic management of the sound environment which is greatly improved or altered, through the environmental magnetic pollution inherent in the presence of electrons with their dual nature, or in the air, it is the electromagnetic aspect of resonance which dominates. The apparatus is adjusted differently depending on where the listening takes place, modified by the presence or absence of significant emitters such as the Eiffel Tower in Paris or in proximity to local emitters, where oscilloscopes show strong electromagnetic disturbances in the audio frequency band, corresponding to our physiological sensibility. FIG. 4 shows an exemplary implanting of two apparatuses called “Real Time Executives” (1-2), each of which supplies an acoustic cabinet (3-4). Each apparatus is mounted on an electrical supply phase (5-6) which connects the amplifier (7) to the cabinets. The amplifier is driven by the laser reader (8). An apparatus could be mounted on each power supply lead of the cabinet. The apparatus or apparatuses may be mounted in any stretch of the power supply of the loudspeaker or loudspeakers. The apparatus or apparatuses could be mounted in the amplifier, or in the cabinets or on a loudspeaker.

The apparatus makes it possible to recover the information that is lost in the radiant electrons through the piezoelectricity which translates the sound information fully into mechanical form in real time through the low mechanical inertia of the components of the piezoelectricity. The piezoelectricity uses silica and makes use of diamond and/or precious stones for their quality of mechanical resonances associated with electrical variations. The use of synthetic artificial stones makes it possible to tailor the grade and efficiency of the apparatuses at lower cost for sound applications that are delicate but pertinent in respect of discrimination, auditory intelligibility. This apparatus, specific to sound, calls upon dual conjugate emission in space, one being mechanical, subtle, supplementing the loudspeakers through the activity of the piezoelectricity of the apparatus and the other is an emission of electromagnetic kind. The two emissions, mechanical and electromagnetic, are associated by successive refinements of the electrical audio components, which are consumed by energy transformations of the apparatus. This dual subtle sound emission is an indispensible supplement for sound reproduction, which becomes perfect. The apparatuses serve the world of electricity in general, all electric machines.

Processors or computers for the control of management or production or onboard computers are directly concerned.

The fields of visual sensitivity, such as lighting for the grasping of graphics images are directly concerned in respect of direct viewing or for photoreprography for example. The fields of audio, audio visual, telephony, radio, and apparatuses in the medical world are directly concerned, both in respect of patients with a hearing impairment and the detection of auditory ailments. The automobile sector and those of aircraft or boats are all indicated to receive this technology, both by electronic management and for all onboard electrical accessories.

Regulation of the quiescence of the electrons is a certain peace within matter itself. The electrons returned to the quiescent state are thus available in their ground state and are well ordered to undertake the novel actions demanded of them.

The apparatus predisposes a novel type of current with electron structure reworked continuously in the quiescent state; this current allows genuine activity in real time, as evidenced in music by these precise aspects marrying together the exactitude of time and the values of the energies which are translated gently into the form of information carried by very low energies. Fundamental compliance with its three precepts means that the grading of the novel RTE current cannot have any imperfection and that the rectified current is not a sufficient condition for the electrical management of machines.

It is obvious that the fragmentation of the electric current, even rectified, is superimposed on the light waves or sound waves, at a stroke preventing waves in the ultraviolet and consequences for the sound waves at periods of 50 or 60 Herz and their multiples. Maxwell, Kirchoff, Gallileo had pointed out the interference thereof and in particular the production of black spectral lines in light.

Apparatus and method opening up a new page in the history of the electric current and its applications. The effects may even be within reach of regulating the direction of electron spin, which would be a refined application of this patent, acting within matter, a refinement never achieved.

1. The method takes into account the activities of electrons within the dual, particle and wave, nature of electron structure, which method involves sorting the active electrons of particle nature and diverting the other inoperative spurious radiant electrons out of the power supply leads to electric machines, electric motors, so that a fragmented original initial electrical signal is returned to the quiescent state in a continuous manner, the structure of the electrons and that which follows must be clean, freed of the memories of the previous activities, the magnetic pollution is diverted from the electrical circuit by piezoelectricity, thereby making it possible to reduce the operating noise of machines, to obtain operational linearity, exceptional efficiency, and all-round comfort without magnetic potential difference, a novel electric current acting in real time (RTE).

2. The method as claimed in claim 1 is useful in the field of computers for avoiding overheating or over-oscillations, and in the world of audio.

3. The method as claimed in claim 1 which is useful in the field of image reproduction, television or cinema for example, or in the lighting of objects for better appreciation of the reliefs of the graphics of colors, having eliminated the electron fragmentation which was previously superimposed on the sound waves or light waves.

4. An apparatus for obtaining a novel electric current active in real time by removing the spurious inoperative radiant electrons which have a tendency to escape, disturbing the active electrons in the power supply leads to electric motors, so as to reduce the vibrations and increase the efficiency thereof, the apparatus or apparatuses are inserted into the electrical supply circuit on at least one phase of the electric socket, which apparatus is a piezoelectric excited by at least one choke, the choke itself consisting of an electrically conducting or superconducting copper wire of for example 1.5 millimeters diameter wound over some 10 turns over a diameter of 10 millimeters and embedded in a piezoelectricity component, this making it possible to trap the radiant electrons removed from the choke, which eradicates them as mechanical motions, the apparatus thus diverts the radiant electrons, and restores the ground state continuity of the nonexcited electrons that is available for any new action.

5. The apparatus as claimed in claim 4 is characterized by the installing of a soundproof shroud.

6. The apparatus as claimed in claim 4 is applicable to the field of computers and medical hardware so as to decrease, among other things, the overheating thereof.

7. The apparatus as claimed in claim 4 characterized in the field of audio by the installation across the terminals of the immersed choke, of at least one choke placed in the open air for an electromagnetic activity of motion synchronous with the harmonics and beats of the linked chokes, associated with the sound-related mechanical effects in the ambient space according to the impedance of the air, which choke is matched to the sound effects of the loudspeakers, and of the piezoelectricity excited, for remarkable spatiality, exceptional subtlety of listening.

8. The apparatus as claimed in claim 7 which can be placed in any stretch of the power supply to the loudspeaker or loudspeakers.

9. The apparatus as claimed in claim 4 characterized by the use of diamond and synthetic stones in the production of the piezoelectricity, for auditory sensitivity, which is delicate, pertinent in respect of discrimination, auditory intelligibility.

10. The apparatus as claimed in claim 4 for organizing the active electrons continuously in the charges of batteries which are 50% more or even double the efficacity.
